(19) United States
(12) Patent Application Publication
(10) Pub. No.: US 2025/0054906 A1
(43) Pub. Date: Feb. 13, 2025

(54) SEMICONDUCTOR DEVICE

(71) Applicant: Taiwan Semiconductor Manufacturing Company, Ltd., Hsinchu (TW)

(72) Inventors: Hsien-Wei Chen, Hsinchu City (TW); Meng-Liang Lin, Hsinchu (TW); Fu Fan, Hsinchu City (TW); Shin-Puu Jeng, Hsinchu (TW)

(73) Assignee: Taiwan Semiconductor Manufacturing Company, Ltd., Hsinchu (TW)

(21) Appl. No.: 18/447,321

(22) Filed: Aug. 10, 2023

(51) Int. Cl. H01L 25/065; H01L 23/31; H01L 23/498; H01L 23/538

(52) U.S. Cl. CPC H01L 25/0655; H01L 23/3128; H01L 23/3135; H01L 23/49811; H01L 23/5383; H01L 24/16; H01L 24/32; H01L 24/73; H01L 2224/16227; H01L 2224/32225; H01L 2224/73204

(57) ABSTRACT

A semiconductor device includes an interposer, a first die, a second die, a third die and a dummy die. The interposer includes a first region and a second region. The first die and the second die are bonded to a first surface of the interposer, the first die is disposed in the first region, and the second die is disposed in the second region. The third die and the dummy die are bonded to a second surface opposite to the first surface of the interposer, wherein the third die is disposed in the first region and the dummy die is disposed in the second region.

### BACKGROUND

The semiconductor industry has experienced rapid growth due to continuous improvements in the integration density of various electronic components (e.g., transistors, diodes, resistors, capacitors, etc.). For the most part, this improvement in integration density has come from repeated reductions in minimum feature size, which allows more of the smaller components to be integrated into a given area. These smaller electronic components may require smaller packages that utilize less area than previous packages. Currently, integrated fan-out packages are becoming increasingly popular for their compactness. How to ensure the reliability of the integrated fan-out packages has become a challenge in the field.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E are schematic cross-sectional views of various stages in a method of forming a semiconductor device according to some embodiments.

FIG. 2 illustrates a schematic cross-sectional view of a semiconductor device according to some embodiments.

FIG. 3 illustrates a schematic cross-sectional view of a semiconductor device according to some embodiments.

FIG. 4 illustrates a top view of a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

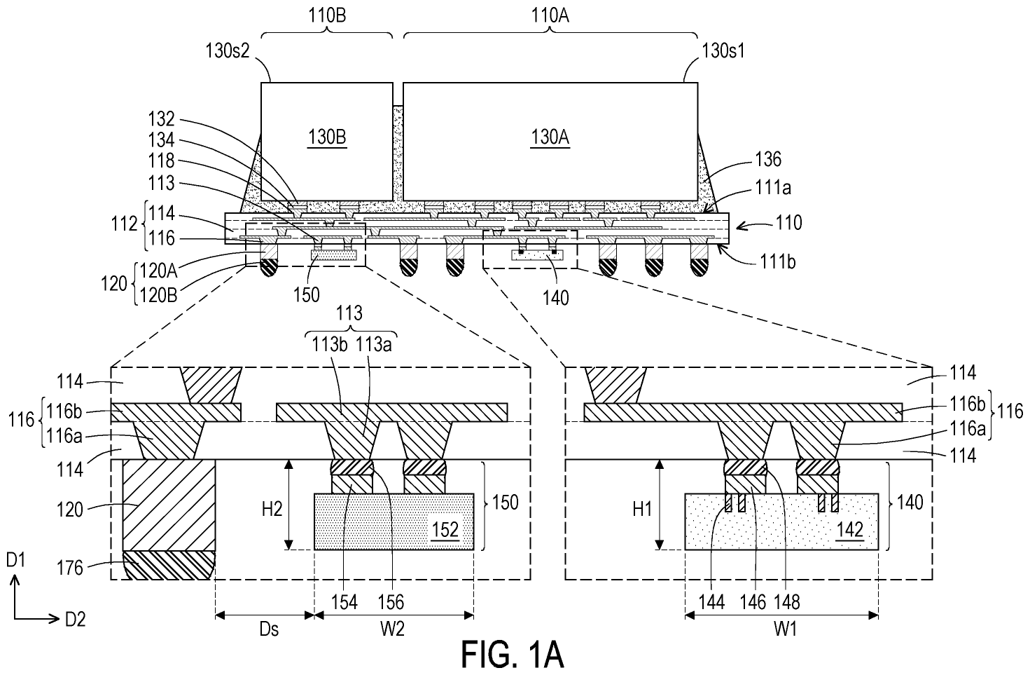

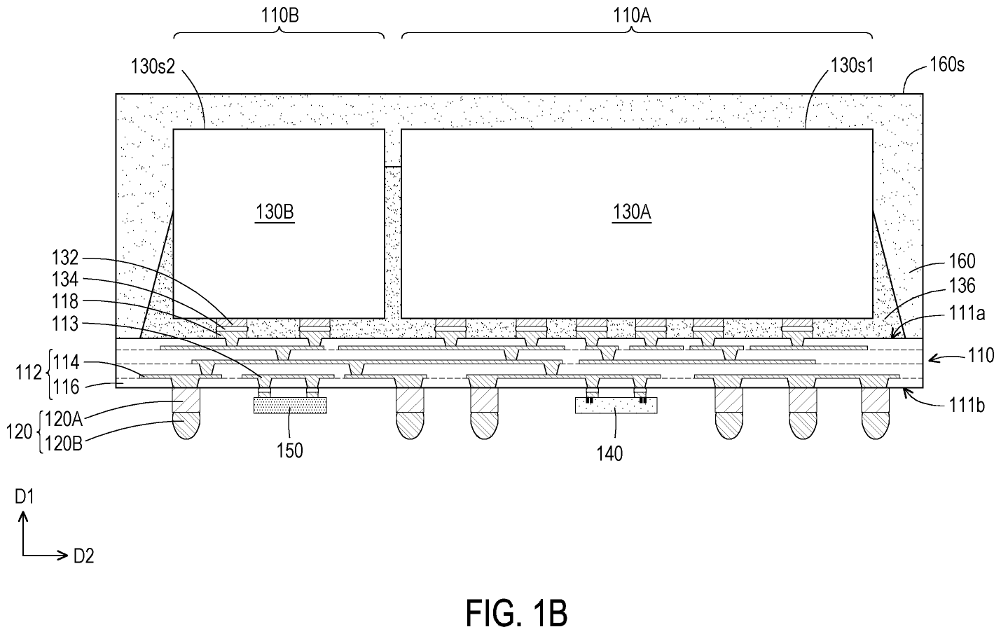

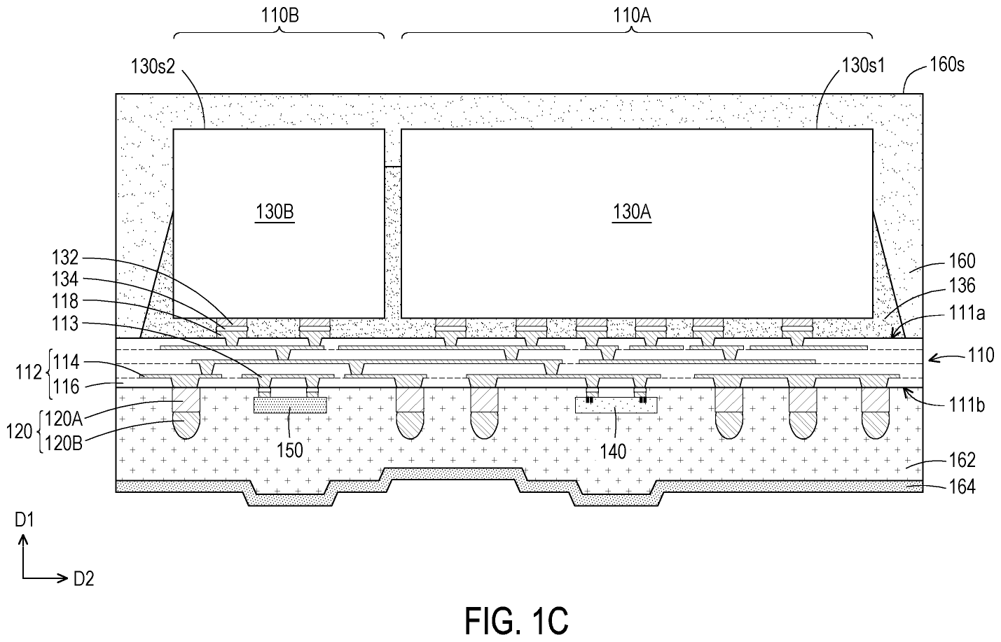

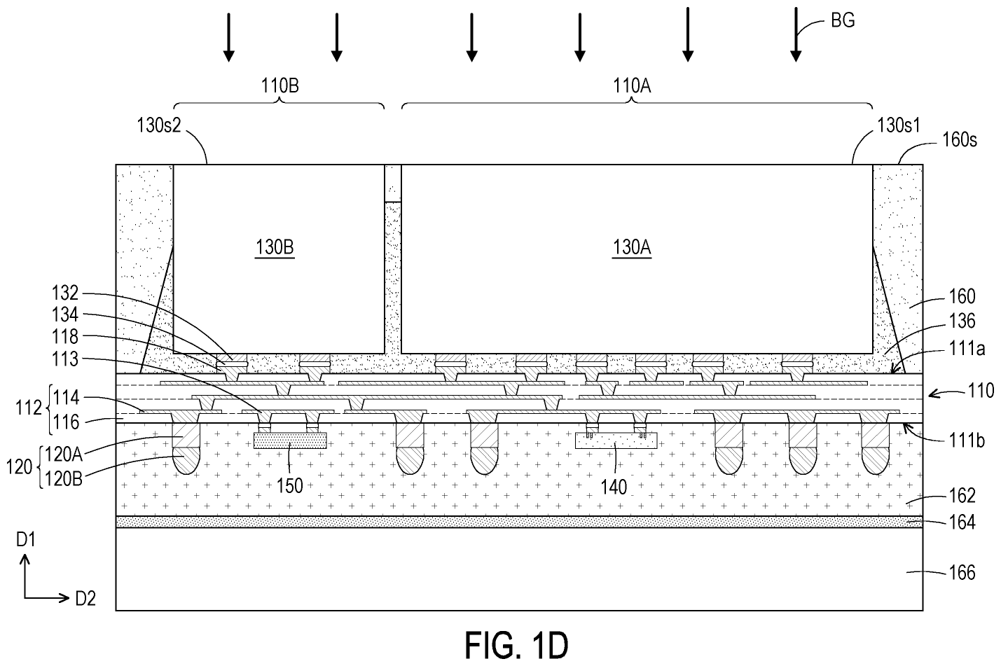

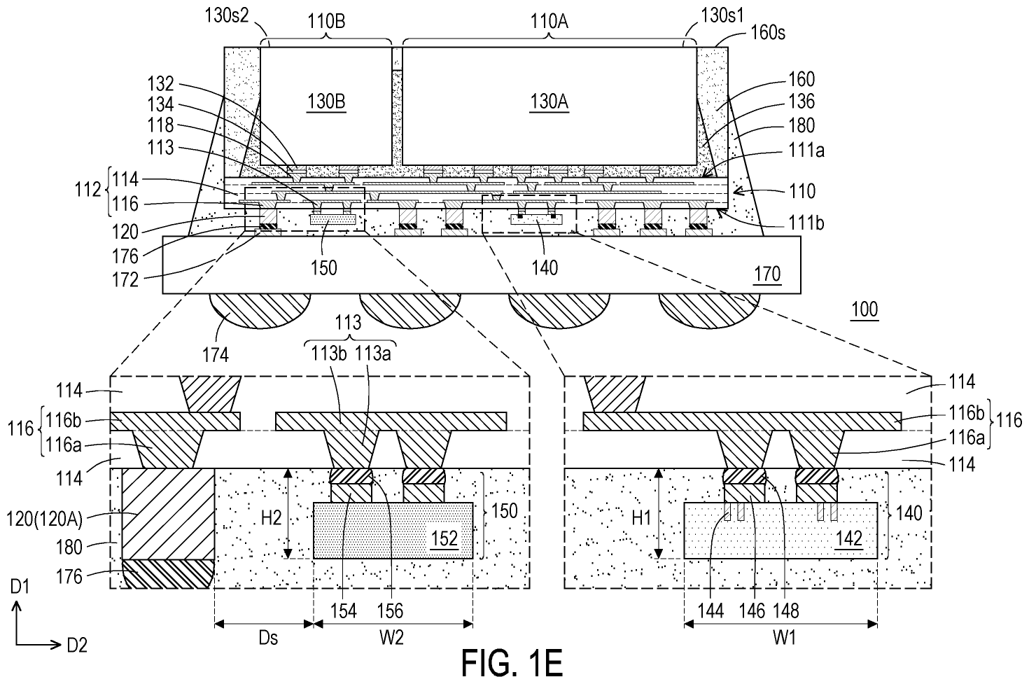

FIG. 1A to FIG. 1E are schematic cross-sectional views of various stages in a method of forming a semiconductor device according to some embodiments.

Referring to FIG. 1A, a plurality of integrated circuits 130A, 130B are bonded to an interposer 110. For example, the integrated circuits 130A, 130B are stacked on the interposer 110 along a first direction D1, and the integrated circuits 130A, 130B and the interposer 110 are respectively extended in a second direction D2. The first direction D1 is also referred to a stacking direction of the integrated circuit 130A, 130B and the interposer 110. The second direction D2 is substantially perpendicular to the first direction D1, for example. The first direction D1 may be z direction, and the second direction may be x direction.

In some embodiments, the interposer 110 is an organic interposer, a silicon interposer or other suitable interposer. In alternative embodiments, the interposer 110 may be other suitable interconnecting structure. In some embodiments, the interposer 110 includes a redistribution layer (RDL) structure 112 and a plurality of conductive connectors 118, 120. The RDL structure 112 may include one or more dielectric layer(s) 114 and respective metallization layer(s) 116 in the dielectric layer(s) 114. In some embodiments, the RDL structure 112 has at least two metallization layers 116. Acceptable dielectric materials for the dielectric layers 114 include low-k dielectric materials such as PSG, BSG, BPSG, USG, or the like. Acceptable dielectric materials for the dielectric layers 114 further include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers 116 may include conductive vias 116a and/or conductive lines 116b to interconnect to one another. The metallization layers 116 may be formed of a conductive material, such as a metal, such as copper, cobalt, aluminum, gold, combinations thereof, or the like. The metallization layers 116 may be formed by a damascene process, such as a single damascene process, a dual damascene process, or the like. In some embodiments, the interposer 110 generally does not include active devices therein. In alternative embodiments, active devices (e.g., transistors, diodes, etc.), capacitors, resistors, the like, or combinations thereof, are formed in and/or on a surface of the interposer 110.

In alternative embodiments (not shown), the interposer 110 may include a semiconductor substrate. The semiconductor substrate may be a substrate of silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In alternative embodiments (not shown), the interposer 110 may include a plurality of conductive vias. The conductive vias may extend into the RDL structure 112 and/or the substrate. The conductive vias are electrically connected to metallization layer(s) 116 of the RDL structure 112. The conductive vias are also sometimes referred to as through substrate vias (TSVs). As an example to form the conductive vias, recesses can be formed in the RDL structure 112 and/or the substrate by, for example, etching, milling, laser techniques, the like, or combinations thereof. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, the like, or combinations thereof. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, the like, or combinations thereof. Examples of conductive materials are copper, tungsten, aluminum, silver, gold, the like, or combinations thereof. Excess conductive material and barrier layer is removed from a surface of the RDL structure 112 or the substrate by, for example, a CMP. Remaining portions of the barrier layer and conductive material form the conductive vias.

The interposer 110 may have conductive connectors 118, 120 at the outermost surfaces 111a, 111b of the interposer 110. The conductive connectors 118 are formed at a first surface 111a of the interposer 110, and the conductive connectors 120 are formed at a second surface 111b of the interposer 110, for example. The second surface 111b is opposite to the first surface 111a. The conductive connectors 118, 120 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 118, 120 may be electrically connected to the RDL structure 112. For example, the conductive connector 118 is disposed on the surface 111a and extends through the dielectric layer 114, to contact the topmost metallization layer 116 of the RDL structure 112. The conductive connector 120 is, for example, disposed on the surface 111b of the interposer 110, to contact the bottommost metallization layer 116 of the RDL structure 112.

The conductive connectors 120 may include underbump metallizations (UBMs) 120A and solder regions 120B over the UBMs 120A. The UBMs 120A may be conductive pillars, pads, or the like. In some embodiments, the UBMs 120A may include a seed layer and a conductive layer. The seed layer may be a metal layer, which may be a single layer or a composite layer including a plurality of sub-layers formed of different materials. In some embodiments, the seed layer includes a titanium layer and a copper layer over the titanium layer. The conductive layer may include a metal, such as copper, titanium, tungsten, aluminum, nickel, or the like. In some embodiments, the UBMs 120A includes three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the UBMs 120A. Any suitable materials or layers of material that may be used for the UBMs 120A are fully intended to be included within the scope of the current application.

The solder regions 120B may include a solder material and may be formed over the UBMs 120A by dipping, printing, plating, or the like. The solder material may include, for example, lead-based and lead-free solders, such as Pb—Sn compositions for lead-based solder; lead-free solders including InSb; tin, silver, and copper (SAC) compositions; and other eutectic materials that have a common melting point and form conductive solder connections in electrical applications. In the illustrated embodiment, the conductive connectors 120 includes C4 bumps. However, the conductive connectors 118, 120 may have other suitable configurations.

The integrated circuits 130A, 130B are the same or different. Each integrated circuit 130A, 130B may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit 130A, 130B may be a stacked device that includes multiple semiconductor substrates (not shown). For example, the integrated circuit 130A, 130B may be a memory device that includes multiple memory dies such as a hybrid memory cube (HMC) device, a high bandwidth memory (HBM) device, or the like. In such embodiments, the integrated circuit 130A, 130B includes multiple semiconductor substrates interconnected by through-substrate vias (TSVs) such as through-silicon vias (not shown). Each of the semiconductor substrates may (or may not) have a separate interconnect structure. In some embodiments, the integrated circuits 130A, 130B are SoC and HBM device. The integrated circuits 130A, 130B may be also referred to as top dies.

In some embodiments, the integrated circuits 130A, 130B have different or the same sizes (e.g., different heights and/or surface areas). For example, the integrated circuits 130A, 130B have different width along the second direction D2. In some embodiments, the integrated circuits 130A, 130B have the same height along the first direction D1. Thus, surfaces (e.g., top surface) 130s1, 130s2 of the integrated circuits 130A, 130B may be substantially coplanar. However, the disclosure is not limited thereto. In alternative embodiments, the integrated circuits 130A, 130B may have different height and/or the surfaces 130s1, 130s2 of the integrated circuits 130A, 130B may be at different heights.

The integrated circuit 130A, 130B may include a semiconductor substrate (not shown), a device layer (not shown) and an interconnect structure (not shown). The semiconductor substrate may be a substrate of silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The device layer may include active devices (e.g., transistors, diodes, etc.), capacitors, resistors, the like, or combinations thereof and an inter-layer dielectric (ILD) surrounding and covering the devices. The ILD may include one or more dielectric layers formed of materials such as phospho-silicate glass (PSG), boro-silicate glass (BSG), boron-doped phospho-silicate glass (BPSG), undoped silicate glass (USG), or the like. Conductive plugs (not separately illustrated) may extend through the ILD to electrically and physically couple the devices. For example, when the devices are transistors, the conductive plugs couple the gates and source and drain regions of the transistors. The conductive plugs may be formed of tungsten, cobalt, nickel, copper, silver, gold, aluminum, the like, or combinations thereof.

The interconnect structure is over the device layer, and is used to electrically connect the devices of the semiconductor substrate. The interconnect structure may be over the ILD and the conductive plugs. The interconnect structure may include one or more dielectric layer(s) and respective metallization layer(s) in the dielectric layer(s). Acceptable dielectric materials for the dielectric layers include low-k dielectric materials such as PSG, BSG, BPSG, USG, or the like. Acceptable dielectric materials for the dielectric layers further include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers may include conductive vias and/or conductive lines to interconnect the devices of the semiconductor substrate. The metallization layers may be formed of a conductive material, such as a metal, such as copper, cobalt, aluminum, gold, combinations thereof, or the like. The interconnect structure may be formed by a damascene process, such as a single damascene process, a dual damascene process, or the like.

In some embodiments, the integrated circuits 130A, 130B include a plurality of conductive connectors 132 at the outermost surfaces (e.g., bottom surfaces) opposite to the surfaces 130s1, 130s2 (e.g., top surfaces). The conductive connectors 132 are similar to the conductive connectors 118, 120 described above, and the description is not repeated herein. In the illustrated embodiment, the conductive connectors 132 include UBMs and solder regions over the UBMs. However, the conductive connectors 132 may have other suitable configurations. In some embodiments, the conductive connectors 132 are in physical contact with respective conductive connectors 118 of the interposer 110, such that the solder regions of the conductive connectors 132 are in physical contact with the respective conductive connectors 118 and form the solder joints 134 therebetween. The solder joints 134 electrically and mechanically couple the integrated circuits 130A, 130B to the interposer 110.

In some embodiments, an underfill 136 is formed around the solder joints 134, and in a gap between the integrated circuits 130A, 130B and the interposer 110. The underfill 136 may reduce stress and protect the solder joints 134. The underfill 136 may be formed of an underfill material such as a molding compound, epoxy, or the like. The underfill 136 may be formed by a capillary flow process after the integrated circuits 130A, 130B are attached to the interposer 110, or may be formed by a suitable deposition method before the integrated circuits 130A, 130B are attached to the interposer 110. The underfill 136 may be applied in liquid or semi-liquid form and then subsequently cured. In some embodiments, the underfill 136 extends along sidewalls of the integrated circuits 130A, 130B. However, the disclosure is not limited thereto. In alternative embodiments, the underfill 136 is omitted. In some embodiments, a surface (e.g., top surface) of the underfill 136 is lower than the surfaces 130s1, 130s2. However, the disclosure is not limited thereto. In alternative embodiments, the surface (e.g., top surface) of the underfill 136 is substantially coplanar with the surfaces 130s1, 130s2.

In some embodiments, the interposer 110 includes a plurality of die regions 110A, 110B. The die regions 110A, 110B are configured to integrated circuits. For example, the integrated circuit 130A is bonded to the die region 110A of the interposer 110, and the integrated circuit 130B is bonded to the die region 110B of the interposer 110. In some embodiments, the die region 110A and the die region 110B are adjacent to each other. In some embodiments, a single integrated circuit 130A and a single integrated circuit 130B are bonded to the interposer 110. However, the disclosure is not limited thereto. There may be more than one integrated circuit 130A and/or one integrated circuit 130B. In such embodiments, there are more than two die regions 110A, 110B.

In some embodiments, the die region 110A is also the region of the interposer 110 to where functional die(s) is bonded, and the die region 110B is also the region of the interposer 110 to where dummy die(s) is bonded. For example, the integrated circuit 130A is bonded to the die region 110A through the surface 111a of the interposer 110, and a functional die 140 is bonded to the die region 110A through the surface 111b of the interposer 110. Similarly, the integrated circuit 130B is bonded to the die region 110B through the surface 111a of the interposer 110, and a dummy die 150 is bonded to the die region 110B through the surface 111b of the interposer 110. In other words, the functional die 140 is disposed corresponding to the integrated circuit 130A, and the dummy die 150 is disposed corresponding to the integrated circuit 130B. In some embodiments, the functional die 140 and the integrated circuit 130A are overlapped along the first direction D1, and the dummy die 150 and the integrated circuit 130B are overlapped along the first direction D1. The functional die 140 is entirely overlapped with the integrated circuit 130A along the first direction D1, and the dummy die 150 is entirely overlapped with the integrated circuit 130B along the first direction D1, for example.

The functional die 140 includes a resistor, a capacitor, an inductor, the like or a combination thereof. In some embodiments, the functional die 140 may be an integrated passive die (IPD), surface mount device (SMD), a large scale integrated (LSI) circuit or other suitable functional die. In some embodiments, the functional die 140 includes a semiconductor substrate 142, a plurality of metal features 144 and a plurality of conductive connectors 146. The metal features 144 may be formed in the semiconductor substrate 142, and the conductive connectors 146 may be formed at the outermost surface of the semiconductor substrate 142. The semiconductor substrate 142 may be a substrate of silicon, doped or undoped, or an active layer of a semiconductor-on-insulator (SOI) substrate. The semiconductor substrate 142 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The metal features 144 of the functional die 140 may be electrically connected to the integrated circuit 130A through the conductive connectors 146. The metal features 144 may be formed of a conductive material, such as a metal, such as copper, cobalt, aluminum, gold, combinations thereof, or the like. In some embodiments, the metal features 144 are also referred to as metal trenches or routings. The functional die 140 may be attached to the interposer 110 through the conductive connectors 146. The conductive connectors 146 may be micro-bumps or other suitable connectors. For example, the solder regions of the conductive connectors 146 are in physical contact with the RDL structure 112 of the interposer 110, and merged with respective metallization layer 116 (e.g., the conductive via 116a of the bottommost metallization layer 116) into solder joints 148 by the reflow process. In some embodiments, the functional die 140 is electrically connected to the interposer 110 through the conductive connectors 146 and the RDL structure 112. In some embodiments, as shown in FIG. 1A, the functional die 140 is disposed between the conductive connectors 120 and separated from the conductive connectors 120. In some embodiments, a distance between the functional die 140 and the conductive connector 120 of the interposer 110 is larger than or equal to 30 μm, so as to prevent the functional die 140 from contacting the conductive connector 120. The distance is measured along the second direction D2, for example. The functional die 140 and the dummy die 150 may be bonded to the interposer 110 after or before the conductive connectors 120 are formed on the interposer 110.

In some embodiments, the dummy die 150 include a semiconductor substrate 152 and a plurality of conductive connectors 154. The semiconductor substrate 152 may be a substrate of silicon, doped or undoped, or an active layer of a semiconductor-on-insulator (SOI) substrate. The semiconductor substrate 142 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The dummy die 150 may be free of conductive features such as metal trenches or routings therein. In other words, the dummy die 150 does not work or has no function. The dummy die 150 may be attached to the interposer 110 through the conductive connectors 154. The conductive connectors 154 may be micro-bumps or other suitable connectors. In some embodiments, the conductive connector 154 of the dummy die 150 is physically connected and/or electrically connected to a dummy pattern 113 of interposer 110. For example, the solder regions of the conductive connectors 154 are in physical contact with the dummy patterns 113 of the interposer 110, and merged with respective dummy pattern 113 into solder joints 156 by the reflow process. The dummy pattern 113 may be disposed in the same dielectric layer 114 as the metallization layer 116 of the RDL structure 112. The dummy pattern 113 may include conductive vias 113a and/or conductive lines 113b to interconnect to one another. In some embodiments, the metallization layer 116 is also referred to as an active conductive pattern while the dummy pattern 113 is also referred to as a dummy conductive pattern. For example, the dummy pattern 113 is at the same level as the bottommost metallization layer 116 (e.g., M1) of the RDL structure 112, and the dummy pattern 113 does not further extend into the dielectric layer 114 as the metallization layer 116 (e.g., M2) immediately adjacent to the bottommost metallization layer 116. In other words, there is no routing between the dummy pattern 113 and the integrated circuit 130A, for example. The dummy pattern 113 may be formed with the metallization layer 116 (e.g., bottommost metallization layer 116) and have the same material as the metallization layer 116 (e.g., bottommost metallization layer 116). The dummy pattern 113 is electrically isolated from the metallization layer 116 of the RDL structure 112 through the dielectric layer 114. For example, the dummy pattern 113 is physically separated from the metallization layers 116, and the dielectric layer 114 is disposed therebetween. In some embodiments, the dummy pattern 113 is electrically floating. Accordingly, the dummy die 150 may be electrically isolated from the RDL structure 112 of the interposer 110 through the dummy pattern 113. After bonding, the dummy die 150 is disposed between and electrically isolated from the conductive connectors 120. In some embodiments, the dummy die 150 may be also referred to as a dummy chiplet or a redundant chiplet. On contrary, the functional die 140 may be also referred to as a functional chiplet.

In some embodiments, the functional die 140 and the dummy die 150 respectively have a height H1, H2 along the first direction D1 and a width W1, W2 along the second direction D2. The height H1, H2 of the functional die 140 and the dummy die 150 is not larger than a height of the conductive connector 120. For example, the height H1, H2 is not larger a height of the UBM of 120A the conductive connectors 120. In some embodiments, a ratio (i.e., H2/H1) of the height H2 of the dummy die 150 to the height H1 of the functional die 140 is in a range of 0.8 and 1.2. The height H2 of the dummy die 150 is in a range of 60 μm and 200 μm, for example. In some embodiments, a ratio (i.e., W2/W1) of the width W2 of the dummy die 150 to the width W1 of the functional die 140 is in a range of 0.5 and 2. The width W2 of the dummy die 150 is in a range of 0.5 mm and 2 mm, for example. In some embodiments, a distance Ds between the dummy die 150 and the conductive connector 120 of the interposer 110 is larger than or equal to 30 μm, so as to prevent the dummy die 150 from contacting the conductive connector 120. The distance Ds is measured along the second direction D2, for example. In some embodiments, the distance Ds between the dummy die 150 and the conductive connector 120 is smaller than, substantially equal to or larger than the distance between the functional die 140 and the conductive connector 120.

Referring to FIG. 1B, an encapsulant 160 is formed over the integrated circuits 130A, 130B. After formation the encapsulant 160, the encapsulant 160 encapsulates the integrated circuits 130A, 130B and the underfill 136. In some embodiments, the encapsulant 160 covers surfaces (e.g., top surfaces) 130s1, 130s2 of the integrated circuits 130A, 130B. For example, a surface 160s of the encapsulant 160 is higher than the surfaces 130s1, 130s2 of the integrated circuits 130A, 130B. The encapsulant 160 may be a molding compound, epoxy, or the like. The encapsulant 160 may or may not include fillers therein. The encapsulant 160 may be applied by compression molding, transfer molding, or the like, and is formed over the surface 111a the interposer 110 such that the integrated circuits 130A, 130B are buried or covered. The encapsulant 160 may be applied in liquid or semi-liquid form and then subsequently cured.

Referring to FIG. 1C and FIG. 1D, a portion of the encapsulant 160 is removed, so as to expose the integrated circuits 130A, 130B. In some embodiments, as shown in FIG. 1C, a package structure of FIG. 1B is placed onto a protection film 162. The protection film 162 may be a tape, such as a backgrinding (BG) tape (UV or non-UV type), which may be used to protect a side of the package structure of FIG. 1B from grinding debris during a subsequent molding material planarization process. The protection film 162 may be applied over the surface 111b of the interposer 110 using, for example, a roller (not shown). The protection film 162 may be a soft adhesive material. For example, the protection film 162 is a thermally foamed tape made of PET. The protection film 162 may have a sufficient thickness to fully cover the conductive connectors 120, the functional die 140 and the dummy die 150, and the thickness of the protection film 162 depends on the height of the conductive connectors 120. In some embodiments, the protection film 162 is conformally formed on the package structure of FIG. 1B. For example, the surface of the protection film 162 is conformal to the surface of the conductive connectors 120, the functional die 140 and the dummy die 150. Then, a release layer 164 may be formed on the protection film 162. The release layer 164 includes polyester, for example. The release layer 164 is conformally formed over the protection film 162, for example.

The topology of the conductive connectors 120 with the functional die 140 is different from the topology of the conductive connectors 120 without the functional die 140. In some embodiments, by disposing the dummy die 150 in the die region 110B corresponding to the functional die 140 in the die region 110A, the side of the package structure of FIG. 1A onto the protection film 162 may have a uniform topology. In other words, the dummy die 150 provides the topology corresponding to the topology of the dummy die 150. Thus, the conductive connectors 120 and the dummy die 150 among the conductive connectors 120 in the die region 110B may collectively provide the topology similar to the topology of the conductive connectors 120 and the functional die 140 among the conductive connectors 120 in the die region 110A. Thus, the protection film 162 formed over the surface 1l1b of the interposer 110 may have a uniform topology across the die region 110A and the die region 110B.

Then, as shown in FIG. 1D, the package structure of FIG. 1A is held by a vacuum chuck 166, and a backside grinding process BG is performed to remove the encapsulant 160 over the integrated circuits 130A, 130B. In some embodiments, since the topology across the package structure is uniform, the protection film 162 and the release layer 164 may be fully adhered to the vacuum chuck 166 without a gap therebetween when the vacuum is provided. For example, an interface between the release layer 164 and the vacuum chuck 166 is substantially flat and at a substantially same height across the entire package structure. Accordingly, the encapsulant 160 over the integrated circuits 130A, 130B may be removed completely without mold residues on the integrated circuits 130A, 130B. That is, the surfaces 130s1, 130s2 of the integrated circuits 130A, 130B are respectively residue-free. On contrary, in an embodiment in which the dummy die is not disposed, due to the nonuniform topology of the package structure, the mold residues may be formed on the integrated circuit without the functional die therebeneath. In such embodiment, a gap may be formed between the release layer and the vacuum chuck when the vacuum is provided, and the interface between the release layer and the vacuum chuck 166 is not flat and has height difference across different regions. This incomplete adherence between the release layer and the vacuum chuck may cause the mold residue after performing the grinding process.

After performing the backside grinding process BG, the surface (e.g., top surface) 160s of the encapsulant 160 is substantially coplanar with the surfaces (e.g., top surface) 130s1, 130s2 of the integrated circuits 130A, 130B, for example. That is, the surfaces (e.g., top surface) 130s1, 130s2 of the integrated circuits 130A, 130B may be completely exposed. In alternative embodiments, the interposer 110 may include a plurality of package regions that may be singulated after formation of the encapsulant 160 and the backside grinding process BG, to form a plurality of package structures. In such embodiments, one of the package regions may include the die regions 110A and 110B, and the package regions are separated by scribe line regions therebetween.

Referring to FIG. 1E, the package structure of FIG. 1D is removed from the vacuum chuck 166, and is attached to a package substrate 170. The package substrate 170 may include conductive connectors 172, 174 on the outermost surfaces. The package substrate 170 may be a printed circuit board or other suitable package substrate. The package substrate 170 may include a substrate core (not shown), which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core may be a SOI substrate. Generally, an SOI substrate includes a layer of a semiconductor material such as epitaxial silicon, germanium, silicon germanium, SOI, SGOI, or combinations thereof. In another embodiment, the substrate core is an insulating core such as a fiberglass reinforced resin core. One example core material is fiberglass resin such as FR4. Alternatives for the core material include bismaleimide-triazine (BT) resin, or alternatively, other printed circuit board (PCB) materials or films.

In some embodiments, the substrate core includes active and functional dies. Devices such as transistors, capacitors, resistors, combinations thereof, and the like may be used to generate the structural and functional requirements of the design for the system. The devices may be formed using any suitable methods. In some embodiments, the substrate core is substantially free of active and functional dies. In some embodiments, the substrate core further includes conductive vias 104, which may be also referred to as TSVs.

The package substrate 170 may include a redistribution structure (not shown). In some embodiments, the redistribution structure is formed of alternating layers of dielectric material (e.g., low-k dielectric material) and conductive material (e.g., copper) with vias interconnecting the layers of conductive material, and is formed through any suitable process (such as deposition, damascene, or the like). In other embodiments, the redistribution structure is formed of alternating layers of dielectric material (e.g., build up films such as Ajinomoto build-up film (ABF) or other laminates) and conductive material (e.g., copper) with vias interconnecting the layers of conductive material, and is formed through any suitable process (such as lamination, plating, or the like).

In some embodiment, the package substrate 170 includes redistribution structures formed on opposing surfaces of the substrate core, such that the substrate core is interposed between the redistribution structure and the redistribution structure. The conductive vias electrically couple the redistribution structure to the redistribution structure. In alternative embodiments, the redistribution structure or the redistribution structure is omitted.

In some embodiments, bond pads (not shown) and a solder resist layer (not shown) are formed on the redistribution structure, with the bond pads being exposed by openings formed in the solder resist layer. The bond pads may be a part of the redistribution structure and may be formed together with other conductive features of the redistribution structure. The solder resist layer may include a suitable insulating material (such as a dielectric material, a polymer material, or the like) and may be formed using any suitable deposition methods.

In some embodiments, the conductive connectors 172, 174 may extend through the opening in the solder resist layer and contact the bond pads. The conductive connectors 172, 174 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In the illustrated embodiment, the conductive connectors 172 may include UBMs, and the conductive connectors 174 may include solder balls. However, the conductive connectors 172, 174 may have other suitable configurations.

In some embodiments, the package structure of FIG. 1D is placed on a surface of the package substrate 170 using, e.g., a pick-and-place tool. After placing the package structure on the package substrate 170, the conductive connectors 120 are in physical contact with respective conductive connectors 172, such that the solder regions 120B (shown in FIG. 1D) of the conductive connectors 120 are in physical contact with the respective conductive connectors 172. In some embodiments, after placing the package structure on the package substrate 170, a reflow process is performed to mechanically and electrically attach the package substrate to the package substrate 170. The reflow process melts and merges the solder regions 120B of the conductive connectors 120 and respective solder materials of the conductive connectors 172 into solder joints 176. The solder joints 176 electrically and mechanically couple the package structure to the package substrate 170.

In some embodiments, an underfill 180 is formed around the solder joints 176, and in a gap between the package structure and the package substrate 170. After formation of the underfill 180, a semiconductor device 100 is formed. The underfill 180 may reduce stress and protect the solder joints 176. The underfill 180 may be formed of an underfill material such as a molding compound, epoxy, or the like. The underfill 180 may be formed by a capillary flow process after the package structure is attached to the package substrate 170, or may be formed by a suitable deposition method before the package structure are attached to the package substrate 170. The underfill 180 may be applied in liquid or semi-liquid form and then subsequently cured. In some embodiments, the underfill 180 extends along the sidewalls of the package structure. For example, the underfill 180 extends along the sidewalls of the interposer 110 and the encapsulant 160. The topmost surface of the underfill 180 is lower than the surfaces 130s1, 130s2, 160s of the integrated circuits 130A, 130B and the encapsulant 160, for example.

In some embodiments, by disposing (integrating) the dummy die 150 corresponding to the functional die 140, the topography of the semiconductor device may be controlled and/or reinforced. In addition, the formation of mold residues may be avoided after packaging. Thus, the yield and performance of the semiconductor device may be improved.

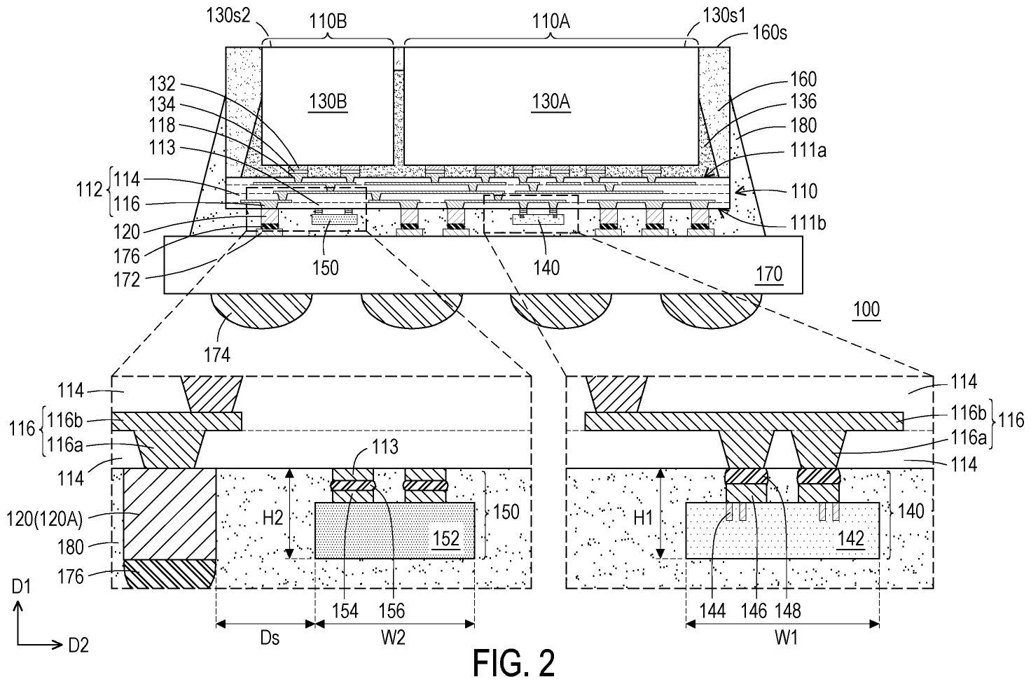

In some embodiments, the dummy pattern 113 of the interposer 110 is formed in the interposer 110 and has a similar configuration as the metallization layer 116. For example, the dummy pattern 113 includes the via portion 113a and the line portion 113b in the dielectric layer 114 of the interposer 110. However, the disclosure is not limited thereto. As shown in FIG. 2A, in some embodiments, the dummy pattern 113 of the interposer 110 is a conductive pad such as a copper pad at the surface 1l1b of the interposer 110. For example, the dummy pattern 113 is formed on the surface 111b of the interposer 110 without extending into the interior of the interposer 110 (e.g., the dielectric layer 114 of the RDL structure 112 in the interposer 110), and the dummy pattern 113 is electrically isolated from the interposer 110. In some embodiments, the dummy die 150 is bonded to the interposer 110 by formation of solder joints 156 between the dummy patterns 113 and the conductive connectors 154. In such embodiments, the dummy pattern 113 of the conductive pad may have a smaller size than the dummy patterns 113 of FIG. 1E, and thus the distance Ds between the dummy die 150 and the conductive connector 120 of the interposer 110 may be further reduced. Accordingly, the design flexibility may be improved and the finer pitch of the conductive connector 120 may be possible.

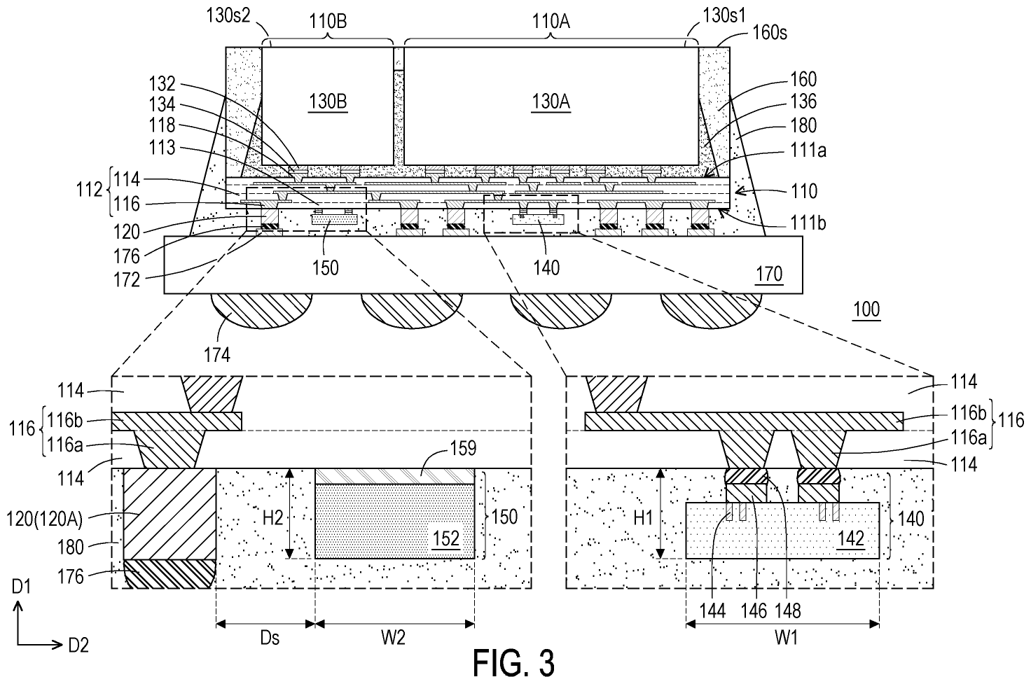

In alternative embodiments, as shown in FIG. 3 the dummy die 150 may be attached to the interposer 110 through an adhesive layer 159. In such embodiments, the dummy pattern 113 may be omitted, and additionally, the conductive connectors 154 may be also omitted. The dummy die 150 may include a semiconductor block such as a silicon block. The adhesive layer 159 may be an epoxy-based adhesive, a rubber-based adhesive or other suitable adhesive. In some embodiments, the adhesive layer 159 may be a thermal interface material (TIM) layer and include a thermal interface material having a high thermal conductivity. In such embodiments, the heat dissipation of the semiconductor device 100 may be improved. In other words, the dummy die 150 may be anchored to the interposer 110 corresponding to the functional die 140 in any suitable way.

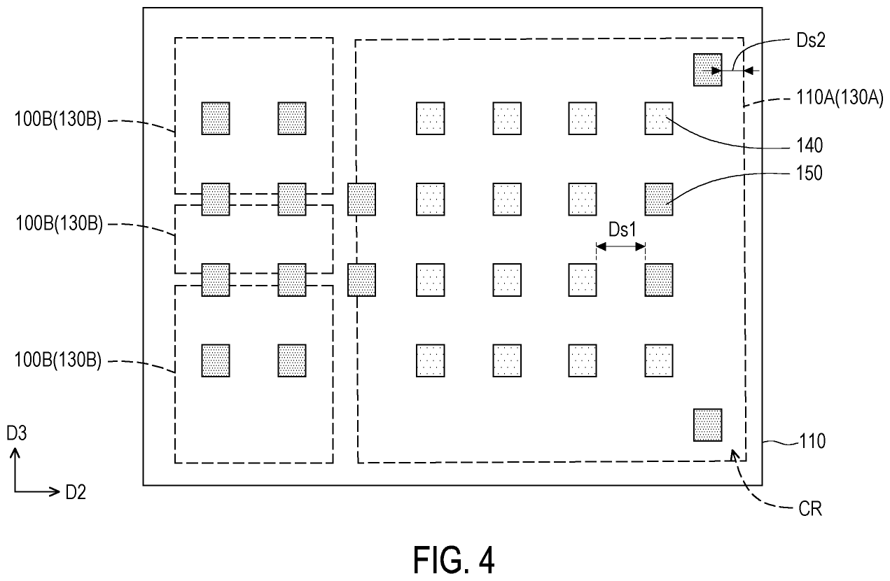

In the above embodiments, one functional die 140 and one dummy die 150 are illustrated. However, the disclosure is not limited thereto. In some embodiments, as shown in FIG. 4, the semiconductor device 100 may include an integrated circuit 130A and a plurality of functional dies 140 in a die region 110A, and a plurality of integrated circuits 130B and a plurality of dummy dies 150 in die regions 110B. Similar to that illustrated in FIG. 1E, the integrated circuit 130A is disposed on the surface 111a of the interposer 110 while the functional dies 140 are disposed on the surface 111b of the interposer 110. The integrated circuits 130B are disposed on the surface 111a of the interposer 110 while the dummy dies 150 are disposed on the surface 111b of the interposer 110. Numbers of the functional dies 140, the dummy dies 150 and the integrated circuits 130A, 130B are for examples only and may be any suitable numbers.

In some embodiments, a plurality of dummy dies 150 (e.g., two dummy dies 150) are disposed in one die region 110B to correspond to the integrated circuit 130B in the respective die region 110B. Furthermore, the dummy dies 150 (e.g., two dummy dies 150) may be disposed between the adjacent two of die regions 110A, 110B. For example, the dummy die 150 (e.g., two dummy dies 150) is disposed between the die regions 110B or between the die region 110A and the die region 110B. In other words, the dummy die 150 is disposed in a die to die area. In some embodiments, the dummy dies 150 may be disposed among the functional dies 140 in the die region 110A where the integrated circuit 130A is disposed. For example, the functional dies 140 and the dummy dies 150 are arranged in an array along the second direction D2 and a third direction D3. The third direction D3 is substantially perpendicular to the first direction D1 and the second direction D2, for example. The first direction D1 may be z direction, the second direction may be x direction, and the third direction D3 may be y direction. A distance Ds1 between the functional die 140 and the dummy die 150 may be the same as or different from a distance between the adjacent two functional dies 150. The distance Ds1 is larger than or equal to 80 μm, for example. In addition, the dummy die 150 may be disposed at a corner region of the die region. For example, as shown in FIG. 4, the dummy die 150 is disposed at the corner region CR of the die region 110A. A distance Ds2 between the dummy die 150 to the edge (also referred to as the die edge) of the die region 110A is larger than or equal to 50 μm, for example. In some embodiments, by disposing (integrating) the dummy die among the functional dies, at the corner of the die region and/or between the die regions, the topography of the semiconductor device may be controlled and/or reinforced, and the formation of the mold residues may be avoided after packaging. Thus, the yield and performance of the semiconductor device may be improved.

According to some embodiments, a semiconductor device includes an interposer, a first die, a second die, a third die and a dummy die. The interposer includes a first region and a second region. The first die and the second die are bonded to a first surface of the interposer, the first die is disposed in the first region, and the second die is disposed in the second region. The third die and the dummy die are bonded to a second surface opposite to the first surface of the interposer, wherein the third die is disposed in the first region and the dummy die is disposed in the second region.

According to some embodiments, a semiconductor device includes an interposer, a first integrated circuit, a second integrated circuit, a functional die and a dummy die. The first integrated circuit and the second integrated circuit are bonded to a first surface of the interposer. The functional die and a dummy die are bonded to a second surface opposite to the first surface of the interposer. The functional die is overlapped with and electrically connected to the first integrated circuit through the interposer, and the dummy die is overlapped with the second integrated circuit.

According to some embodiments, a semiconductor device includes an interposer, a first integrated circuit, a plurality of functional dies and at least one dummy die. The interposer includes a first region. The first integrated circuit is bonded to a first surface of the interposer and disposed in the first region. The functional dies and the dummy die are attached to a second surface opposite to the first surface of the interposer, wherein the functional dies and the at least one first dummy die are disposed in the first region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an interposer, comprising a first region and a second region;
a first die and a second die, bonded to a first surface of the interposer, the first die disposed in the first region, and the second die disposed in the second region; and
a third die and a dummy die, bonded to a second surface opposite to the first surface of the interposer, wherein the third die is disposed in the first region and the dummy die is disposed in the second region.

2. The semiconductor device of claim 1, wherein the first die and the third die are overlapped along a stacking direction of the first die and the interposer, and the second die and the dummy die are overlapped along the stacking direction.

3. The semiconductor device of claim 1, wherein the third die is electrically connected to the first die through the interposer, and the dummy die is electrically isolated from the second die.

4. The semiconductor device of claim 1, wherein the interposer comprises at least one active conductive pattern and at least one dummy conductive pattern, the third die is electrically connected to the at least one active conductive pattern, and the dummy die is electrically connected to the at least one dummy conductive pattern.

5. The semiconductor device of claim 4, wherein the at least one active conductive pattern and the at least one dummy conductive pattern are provided within a same dielectric layer.

6. The semiconductor device of claim 1, further comprising a plurality of conductive connectors disposed on the second surface of the interposer, wherein the third die and the dummy die are respectively disposed between adjacent two of the conductive connectors.

7. The semiconductor device of claim 1, further comprising an underfill surrounding the interposer, the third die and the dummy die.

8. The semiconductor device of claim 1, wherein the third die is an integrated passive die (IPD), a surface mount device (SMD) or a large scale integrated (LSI) circuit.

9. A semiconductor device, comprising:
an interposer;
a first integrated circuit and a second integrated circuit, bonded to a first surface of the interposer; and
a functional die and a dummy die, bonded to a second surface opposite to the first surface of the interposer, wherein the functional die is overlapped with and electrically connected to the first integrated circuit through the interposer, and the dummy die is overlapped with the second integrated circuit.

10. The semiconductor device of claim 9, further comprising a first encapsulant disposed on the first surface of the interposer, wherein the first encapsulant encapsulates the first integrated circuit and the second integrated circuit, and a top surface of the first encapsulant is substantially coplanar with top surfaces of the first integrated circuit and the second integrated circuit.

11. The semiconductor device of claim 9, further comprising a first encapsulant disposed on the first surface of the interposer and a second encapsulant between the first integrated circuit and the second integrated circuit, wherein the first encapsulant encapsulates the first integrated circuit, the second integrated circuit and the second encapsulant.

12. The semiconductor device of claim 9, further comprising a first encapsulant disposed on the first surface of the interposer and a third encapsulant, wherein the third encapsulant encapsulates the functional die, the dummy die and the first encapsulant.

13. The semiconductor device of claim 9, wherein the dummy die comprises a plurality of conductive connectors bonded to the second surface of the interposer without extending into the interposer.

14. The semiconductor device of claim 9, further comprising a package substrate, wherein the interposer is bonded to the substrate, and the functional die and the dummy die are disposed between the interposer and the package substrate.

15. A semiconductor device, comprising:
an interposer, comprising a first region;
a first integrated circuit, bonded to a first surface of the interposer and disposed in the first region; and
a plurality of functional dies and at least one dummy die, attached to a second surface opposite to the first surface of the interposer, wherein the functional dies and the at least one first dummy die are disposed in the first region.

16. The semiconductor device of claim 15, wherein the at least one first dummy die is disposed between the functional dies.

17. The semiconductor device of claim 15, wherein the functional dies and the at least one dummy die are disposed in an array.

18. The semiconductor device of claim 15, wherein the at least one second dummy die is disposed at a corner region of the first region.

19. The semiconductor device of claim 15, further comprising:
a second integrated circuit, bonded to the first surface of the interposer and disposed in a second region of the interposer; and
at least one second dummy die, bonded to the second surface opposite to the first surface of the interposer and disposed in the second region of the interposer.

20. The semiconductor device of claim 15, further comprising:
a second integrated circuit, bonded to the first surface of the interposer and disposed in a second region of the interposer; and
at least one second dummy die, bonded to the second surface opposite to the first surface of the interposer and disposed between the first region and the second region or between the second regions of the interposer.
